(19) United States
(12) Patent Application Publication
(10) Pub. No.: US 2025/0175068 A1
(43) Pub. Date: May 29, 2025

(54) MAGNETIC TRACK BASE FOR A STATIONARY PART OF A LINEAR MOTOR

(71) Applicant: ETEL S.A., Môtiers (CH)

(72) Inventors: Philippe TAMIGNIAUX, Morteau (FR); Yannick DROVAL, Neuchâtel (CH)

(21) Appl. No.: 18/941,383

(22) Filed: Nov. 8, 2024

(30) Foreign Application Priority Data
Nov. 23, 2023 (EP) 23211827.3

(51) Int. Cl. H02K 41/02; H02K 5/00

(52) U.S. Cl. CPC H02K 41/02; H02K 5/00

(57) ABSTRACT

A magnetic track base for a stationary part of a linear motor includes a magnetic receiving portion configured to fixedly receive permanent magnets, rail receiving portions configured to fixedly receive rails along both sides of the magnets receiving portion, and an encoder scale support receiving portion configured to fixedly receive an encoder scale support. The encoder scale support receiving portion includes a plurality of decoupled tabs mechanically decoupled from the rest of the magnetic track base and arranged to receive a bottom side of the encoder scale support to prevent, or at least reduce, deformation of the encoder scale support receiving portion that may be caused from the deformation of the rest of the magnetic track base when the track base is subjected to external forces.

### CROSS-REFERENCE TO RELATED APPLICATIONS

The present application claim priority to application Ser. No. 23/211,827.3, filed in the European Patent Office on Nov. 23, 2023, which is expressly incorporated herein in its entirety by reference thereto.

### FIELD OF THE INVENTION

The present invention relates to a magnetic track base for a stationary part of a linear motor. The present invention also relates to a motion-positioning system, e.g., a wafer positioning system, that includes at least one linear motor with its stationary part including the magnetic track base.

### BACKGROUND INFORMATION

X-Y motion-positioning systems require high precision linear encoders to provide accurate positioning. Encoder scales must therefore remain as stable as possible while withstanding external disturbances to avoid a loss of accuracy.

Encoder scale supports are generally screwed onto a magnetic track base together with other components, such as mechanical bearing rails, and magnets of the magnetic track, without any particular configuration on the magnetic track base. In most cases, the scale and the carrier are formed of materials with different thermal expansion behavior. The stationary fixation must therefore be arranged such that no constraining forces are exerted on the scale by the carrier when the temperature changes.

Some encoder scale support geometry, such as that described in European Patent Document No. 3 705 850 can be quite insensitive to some perturbations by adding to it decoupling devices, such as hinge and leaf. This approach is, however, rather complex to implement and therefore expensive.

### SUMMARY

Example embodiments of the present invention provide a magnetic track base for a stationary part of a linear motor, which does not exhibit the foregoing disadvantages.

Example embodiments provide a magnetic track base that includes an encoder scale support receiving portion that does not deform when subjected to external forces, or at least in a lesser magnitude than conventional scale supports.

Example embodiments provide a magnetic track base that is readily produced and is cost-effective.

According to example embodiments, a magnetic track base for a stationary part of a linear motor includes a magnetic receiving portion configured to fixedly receive permanent magnets, rail receiving portions configured to fixedly receive rails along both sides of the magnets receiving portion, and an encoder scale support receiving portion configured to fixedly receive an encoder scale support. The encoder scale support receiving portion includes a plurality of decoupled tabs mechanically decoupled from the rest of the magnetic track base and arranged to receive a bottom side of the encoder scale support to prevent, or at least reduce, deformation of the encoder scale support receiving portion that may be caused from the deformation of the rest of the magnetic track base when the track base is subjected to external forces.

According to example embodiments, the plurality of decoupled tabs includes a corresponding plurality of fixation tabs and decoupling members for mechanical decoupling between each fixation tab and the rest of the magnetic track base.

According to example embodiments, each decoupling member is arranged a cut-out part arranged around a corresponding fixation tab.

According to example embodiments, each cut-out part is arranged in the form of a U-shape through-groove extending from a top side to a bottom side of the magnetic track base.

According to example embodiments, each fixation tab includes a top flat surface having a fixation hole. The surface is raised above the surface of the magnetic receiving portion.

According to example embodiments, the plurality of fixation tabs is arranged along a longitudinal direction between the magnetic receiving portion and one rail receiving portion.

According to example embodiments, the magnetic receiving portion includes a plurality of pairs of threaded holes for fixing permanent magnets with screws and a plurality of pairs of through-holes for fixing the magnetic track base to a magnetic track base support.

According to example embodiments, the cut-out parts each surrounds one through-hole of the pairs of through-holes for fixing the magnetic track base to the magnetic track base support such that the fixation tabs are rigidly fixed to the support.

According to example embodiments, the magnetic track base is arranged as a monobloc.

According to example embodiments, the encoder scale support has a predominantly constant L-shaped cross-section along its length forming a stand that is fixed onto the encoder scale support receiving portion.

According to example embodiments, a stationary part of a linear motor includes the magnetic track base as described herein, magnets fixed to the magnetic receiving portion, rails fixed on rail receiving portions on both sides of the magnets, an encoder scale support fixed to the encoder scale support receiving portion, and an encoder scale fixed to the encoder scale support.

According to example embodiments, a linear motor includes the stationary part as described herein and a mobile part that includes a coil assembly, sliders slidably engaged with respective rails of the stationary part, and an optical reader adapted to move along the encoder scale.

According to example embodiments, a motion-positioning system, e.g., a wafer positioning system, includes the linear motor described herein.

Further features and aspects of example embodiments of the present invention are described in more detail below with reference to the appended schematic Figures.

### BRIEF DESCRIPTION OF THE DRAWINGS

FIG. 1 is a perspective view of a magnetic track base.

FIG. 2 is an enlarged view of one of the plurality of fixation tabs illustrated in FIG. 1.

FIG. 3 is a perspective view of the encoder scale support adapted to be fixed to the encoder scale support receiving portion of the magnetic track base illustrated in FIG. 1.

FIG. 4a illustrates a simulation of the magnetic track that includes the encoder scale support when exposed to external force of 5,000 N with the deformation of the part being amplified twenty thousand times.

FIG. 4b illustrates a simulation of the encoder scale support illustrated in FIG. 4a with the deformation of the scale support amplified a hundred thousand times.

FIG. 5a illustrates a simulation of a conventional magnetic track including the encoder scale support when exposed to external force of 5,000 N with the part subjected to deformation amplified twenty thousand times.

FIG. 5b illustrates a simulation of the encoder scale support illustrated in FIG. 5a with the deformation of the scale support amplified a hundred thousand times.

FIG. 6 is a perspective view of a wafer positioning system that includes a motion system having, or consisting of, x and y linear motors both including the magnetic track base.

FIG. 7 is a perspective view of the motion system of the wafer positioning system illustrated in FIG. 6 with some parts hidden to highlight the encoder scale support.

FIG. 8 is a side view of the motion system illustrated in FIG. 6.

### DETAILED DESCRIPTION

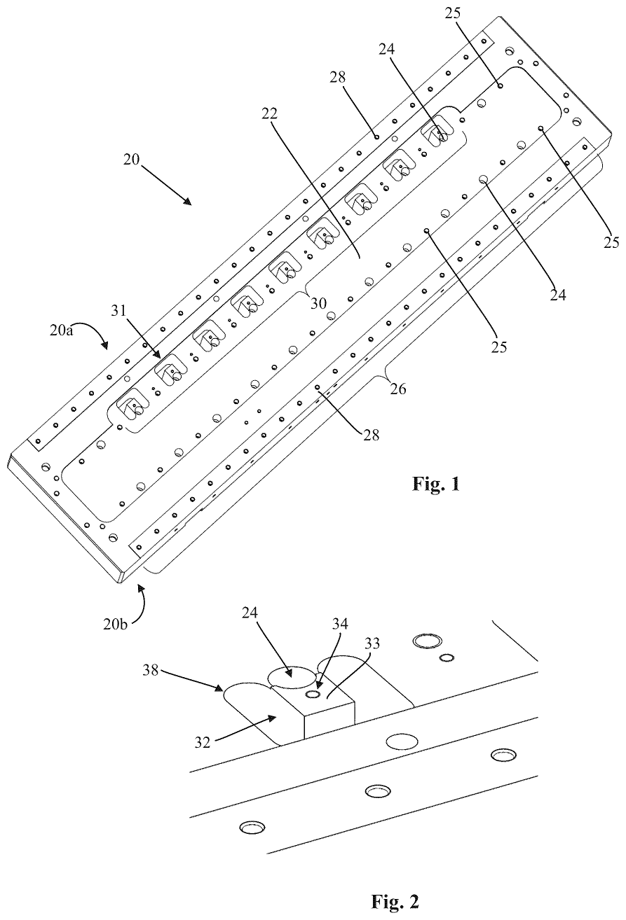

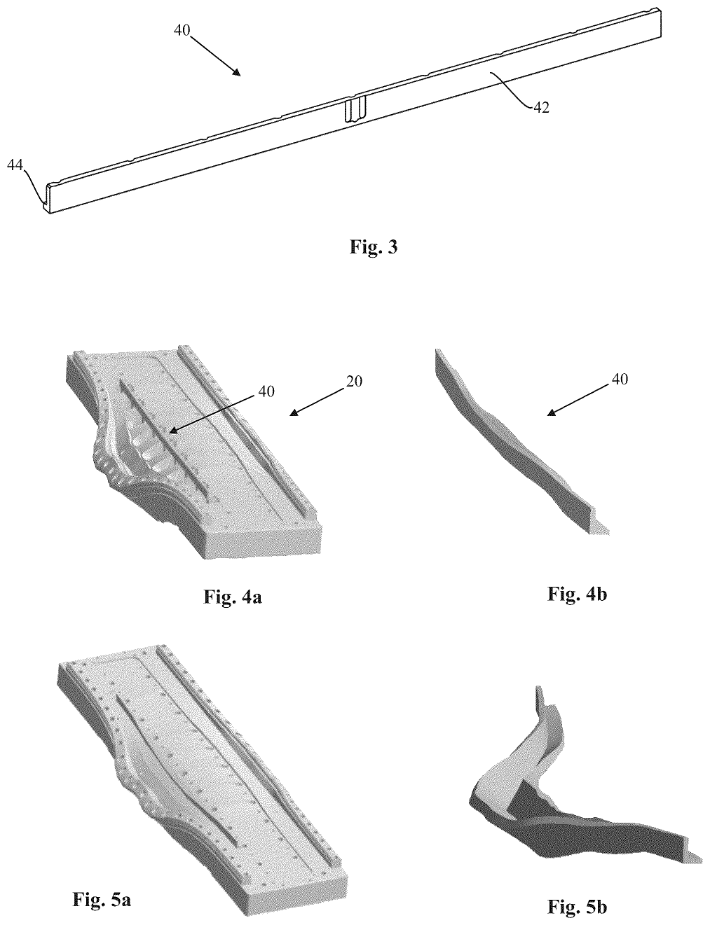

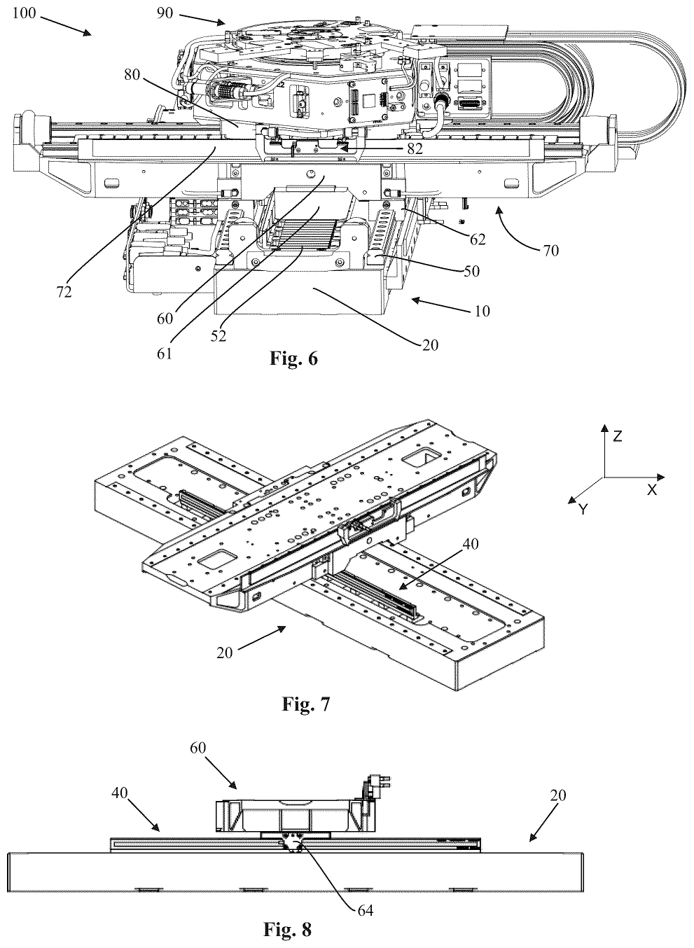

With reference to FIG. 1, the magnetic track base 20 is specifically adapted to support the encoder scale support 40 illustrated in FIG. 3 with no or minimal deformation of the scale support 40 when subjected to external forces. The magnetic track base 20 is configured to be integrated in a stationary part 10 of a linear motor of a motion-positioning system, e.g., a wafer positioning system 100 as illustrated in FIGS. 6 to 8.

The magnetic track base 20 is configured to support permanent magnets 52 and rails 50 that are slidably engaged with sliders 62 of a movable part 60 that includes a coil assembly 61. The coil assembly includes a set of electromagnetic coils that are wrapped around an iron core and are adapted to be sequentially energized to displace the movable part 60 above and along the magnetic track made of the permanent magnets 52.

The external forces are of different natures, such as the attraction forces between the magnets and the iron core of the movable part, thermal stress induced by the differential thermal expansion between the rails 50 and the magnetic track base 20, and mechanical strain in the rails induced by non-perfect alignment between the rails 50 and the sliders 62 of respective stationary and movable parts 10, 60.

The magnetic track base 20 includes a magnetic receiving portion 22 configured to fixedly receive permanent magnets 52, rail receiving portions 26 configured to fixedly receive rails 50 along both sides of the magnetic receiving portion 22, and an encoder scale support receiving portion 30 configured to fixedly receive the encoder scale support 40. The magnetic receiving portion 22 includes a plurality of pairs of threaded holes 25 for fixing permanent magnets 52 with screws and a plurality of pairs of through-holes 24 for fixing the magnetic track base 20 to a support.

The encoder scale support receiving portion 30 includes a plurality of decoupled tabs 31 mechanically decoupled from the rest of the magnetic track base 20. In the illustrated example embodiment, the plurality of decoupled tabs 31 includes fixation tabs 32 arranged along a longitudinal direction between the magnetic receiving portion 22 and a rail receiving portion 26 of the magnetic track base 20. A corresponding plurality of decoupling members 38 are arranged around each fixation tabs 32 for mechanical decoupling between each fixation tab 32 and a longitudinal side of the magnetic track base 20. The decoupling members 38 may be, for example, arranged as cut-out parts 38 that are each arranged around respective fixation tab 32 and surrounding a through-hole 24 such that the fixation tabs 32 are rigidly fixed to the magnetic track base support.

Referring to FIG. 2, each fixation tab 32 includes a top flat surface 33 that is raised above the surface of the magnetic receiving portion 22 such that the encoder scale support 40 is distant and elevated from the magnets receiving portion 22. Each cut-out part 38 is arranged in the form of a U-shaped through-groove extending from a top side 20a to a bottom side 20b of the magnetic track base 20. Fillets may be provided so that the groove can be readily milled in the base.

Referring to FIG. 3, the encoder scale support 40 has a predominantly or substantially constant L-shaped cross-section along its length, forming a stand 44 that is fixed onto the encoder scale support receiving portion 30 and a scale receiving side 42 on which is fixed an encoder scale. The scale receiving side 42 may include grooves for gluing the encoder scale at its reference point. The top flat surface 33 of the fixation tabs 32 may include a fixation hole 34 to screw the stand 44 of the encoder scale support 40 onto the encoder scale support receiving portion 30.

The cut-out parts 38 of the encoder scale support receiving portion 30 onto which is fixed the encoder scale support 40 allow for mechanically decoupling the scale support 40 from the rest of the magnetic track base 20. As a consequence, deformation of the magnetic track base 20 induced by external forces, as those mentioned above, does not negatively impact the shape of the encoder scale support receiving portion 30, or at least in a lesser magnitude than conventional scale support receiving portions. Thus, the deformation of encoder scale support 40 does not occur or occurs within an acceptable range for high-precision positioning.

The magnetic track base 20 is a monolithic piece generally made of aluminum and is formed by a milling process. As illustrated FIGS. 4a to 5b, the encoder scale support of the magnetic track base, according to the example embodiment illustrated in FIG. 1, is much less impacted by the deformation of the rest of the magnetic track base as opposed to a conventional magnetic track base. Indeed, the encoder scale support deformation is decreased by more than fivefold in comparison with a conventional magnetic track without mechanical decoupling. The foregoing improvement is also obtained for other mechanical bearing perturbations. For example, when using recirculating ball or roller bearings for the sliders 62, the balls or rollers circulate, moving from the return zone to the load-carrying zone. This can create a periodic force perturbation from which the encoder scale support must be decoupled.

The wafer positioning system 100 illustrated in FIGS. 6 to 8 includes a first linear motor, as described above, and a second linear motor including a stationary part 70 mounted on the moveable part 60 of the first linear motor, the moveable part 60 being equipped with an optical position sensor unit 64 arranged to move along the encoder scale so as to be positioned precisely along the X-axis of the coordinates system of the wafer positioning system 100. The stationary part 70 of the second linear motor also includes an encoder scale support 72 on which is fixed an encoder scale. A wafer stage 90 is mounted on moveable part 80 of the second linear motor, the moveable part 80 being equipped with an optical position sensor unit 82 arranged to move along the encoder scale so as to be positioned precisely along the Y-axis of the coordinates system of the wafer positioning system 100.

### REFERENCE NUMERAL LIST

10 Stationary part
20 Magnetic track base
20a Top side
20b Bottom side
22 Magnets receiving portion
24 First set of fixation holes
25 Second set of fixation holes
26 Rail receiving portion
28 Fixation holes
30 Encoder scale support receiving portion
31 Decoupled tabs
32 Fixation tabs
33 Flat surfaces
34 Holes
38 Decoupling members (e.g., cut-out parts)
40 Encoder scale support
42 Scale receiving side
44 Stand
50 Rails
52 Magnets
60 Movable part
61 Coil assembly
62 Sliders
64 Optical position sensor unit
70 Stationary part
72 Encoder scale support
80 Movable part
82 Optical position sensor unit
90 Wafer stage
100 Wafer positioning system

What is claimed is:

1. A magnetic track base for a stationary part of a linear motor, comprising:
a magnet receiving portion adapted to fixedly receive permanent magnets;
rail receiving portions adapted to fixedly receive rails along both sides of the magnets receiving portion; and
an encoder scale support receiving portion adapted to fixedly receive an encoder scale support;
wherein the encoder scale support receiving portion includes a plurality of decoupled tabs mechanically decoupled from the rest of the magnet track base and adapted to receive a bottom side of the encoder scale support to prevent or at least reduce deformation of the encoder scale support receiving portion caused from deformation of the rest of the magnetic track base in response to the track base being subjected to external forces.

2. The magnetic track base according to claim 1, wherein the decoupled tabs include a corresponding plurality of fixation tabs and decoupling members mechanical decoupling between each fixation tab and the rest of the magnetic track base.

3. The magnetic track base according to claim 2, wherein each decoupling member includes a cut-out part arranged around a corresponding fixation tab.

4. The magnetic track base according to claim 3, wherein the cut-out part is arranged as a U-shaped through-groove extending from a top side of the magnetic track base to a bottom side of the magnetic track base.

5. The magnetic track base according to claim 2, wherein each fixation tab has a top flat surface including a fixation hole, the top flat surface being raised above a surface of the magnet receiving portion.

6. The magnetic track base according to claim 2, wherein the fixation tabs are arranged along a longitudinal direction between the magnet receiving portion and one of the rail receiving portions.

7. The magnetic track base according to claim 1, wherein the magnet receiving portion includes a plurality of pairs of threaded holes adapted to fix the permanent magnets with screws and a plurality of pairs of through-holes adapted to fix the magnetic track base to a magnet track base support.

8. The magnetic track base according to claim 3, wherein the magnet receiving portion includes a plurality of pairs of threaded holes adapted to fix the permanent magnets with screws and a plurality of pairs of through-holes adapted to fix the magnetic track base to a magnet track base support.

9. The magnetic track base according to claim 8, wherein each of the cut-out parts surrounds a corresponding one of the through-holes of the pairs of through-holes, the fixation tabs being rigidly fixed to the magnet track base support.

10. The magnetic track base according to claim 1, wherein the magnetic track base is arranged as a monobloc.

11. The magnetic track base according to claim 1, wherein the encoder scale support has a substantially constant L-shaped cross-section along a length of the encoder scale support to form a stand that is fixed onto the encoder scale support receiving portion.

12. The magnetic track base according to claim 1, wherein the magnetic track base is arranged as a monolithic piece of aluminum.

13. The magnetic track base according to claim 11, wherein the encoder scale support includes a scale receiving side on one leg of the L-shaped cross-section.

14. The magnetic track base according to claim 13, wherein the scale receiving side includes grooves to glue an encoder scale at a reference point.

15. The magnetic track base according to claim 5, wherein the encoder scale support has a substantially constant L-shaped cross-section along a length of the encoder scale support to form a stand that is fixed onto the encoder scale support receiving portion by screws screwed into the fixation holes.

16. The magnetic track base according to claim 5, wherein the encoder scale support is arranged on the top flat surface and is raised above the surface of the magnet receiving portion.

17. The magnetic track base according to claim 1, wherein the rails are adapted to slidably engage with sliders of a movable part that includes a coil assembly.

18. A stationary part of a linear motor, comprising:
a magnetic track base including a magnet receiving portion, rail receiving portions, and an encoder scale support receiving portion;
magnets fixed to the magnet receiving portion;
rails fixed on the rail receiving portions on both sides of the magnets;
an encoder scale support fixed to the encoder scale support receiving portion; and
an encoder scale fixed to the encoder scale support;
wherein the encoder scale support receiving portion includes a plurality of decoupled tabs mechanically decoupled from the rest of the magnet track base and receiving a bottom side of the encoder scale support to prevent or at least reduce deformation of the encoder scale support receiving portion caused from deformation of the rest of the magnetic track base in response to the track base being subjected to external forces.

19. A linear motor, comprising:
a stationary part including:
a magnetic track base including a magnet receiving portion, rail receiving portions, and an encoder scale support receiving portion;
magnets fixed to the magnet receiving portion;
rails fixed on the rail receiving portions on both sides of the magnets;
an encoder scale support fixed to the encoder scale support receiving portion; and
an encoder scale fixed to the encoder scale support; and
a mobile part including a coil assembly, sliders slidably engaged with respective rails of the stationary part, and an optical reader movable along the encoder scale;
wherein the encoder scale support receiving portion includes a plurality of decoupled tabs mechanically decoupled from the rest of the magnet track base and receiving a bottom side of the encoder scale support to prevent or at least reduce deformation of the encoder scale support receiving portion caused from deformation of the rest of the magnetic track base in response to the track base being subjected to external forces.

20. A motion-positioning system, comprising:
a linear motor, including:
a stationary part including:
a magnetic track base including a magnet receiving portion, rail receiving portions, and an encoder scale support receiving portion;
magnets fixed to the magnet receiving portion;
rails fixed on the rail receiving portions on both sides of the magnets;
an encoder scale support fixed to the encoder scale support receiving portion; and
an encoder scale fixed to the encoder scale support; and
a mobile part including a coil assembly, sliders slidably engaged with respective rails of the stationary part, and an optical reader movable along the encoder scale;
wherein the encoder scale support receiving portion includes a plurality of decoupled tabs mechanically decoupled from the rest of the magnet track base and receiving a bottom side of the encoder scale support to prevent or at least reduce deformation of the encoder scale support receiving portion caused from deformation of the rest of the magnetic track base in response to the track base being subjected to external forces.

21. The motion-positioning system according to claim 20, wherein the motion-positioning system is arranged as a wafer positioning system.
